(19) United States
(12) Patent Application Publication
(10) Pub. No.: US 2024/0402021 A1
(43) Pub. Date: Dec. 5, 2024

(54) TEMPERATURE CALIBRATION SYSTEM, INSPECTION APPARATUS, AND TEMPERATURE CALIBRATION METHOD

(71) Applicant: Tokyo Electron Limited, Tokyo (JP)

(72) Inventors: Tomohiro OTA, Yamanashi (JP); Shigeru KASAI, Yamanashi (JP); Yasuhiro MURATA, Yamanashi (JP); Fumiya FUJII, Yamanashi (JP)

(21) Appl. No.: 18/694,153

(22) PCT Filed: Sep. 15, 2022
(86) PCT No.: PCT/JP2022/034604

§ 371 Date: Mar. 21, 2024

(30) Foreign Application Priority Data
Sep. 30, 2021 (JP) 2021-162244

(51) Int. Cl. G01K 15/00; G01K 1/143; G01K 3/14; G01R 31/26; G01R 31/28; G01R 35/00

(52) U.S. Cl. CPC G01K 15/005; G01K 1/143; G01K 3/14; G01R 31/2601; G01R 31/2831; G01R 31/2874; G01R 35/005

(57) ABSTRACT

A temperature calibration system includes: an inspection apparatus to adjust temperature of an inspection target in a placement part and inspect the inspection target; and a surface thermometer, and is configured to calibrate temperature sensors in the placement part. The inspection apparatus includes: a carriage to move the placement part in X-, Y-, and Z-axis directions; and a controller to perform a calibration process to measurement values of the temperature sensors. The surface thermometer is configured to contact a placement surface of the placement part and detect a surface temperature of the placement surface. The controller is configured to: control the carriage to contact the surface thermometer with a detection position of the placement surface of the placement part; detect the surface temperature of the detection position by the surface thermometer; and calibrate the measurement value of the temperature sensor corresponding to the detection position based on the surface temperature.

### TECHNICAL FIELD

The present disclosure relates to temperature calibration systems, inspection apparatuses, and temperature calibration methods.

### BACKGROUND ART

Inspection apparatuses for performing an electrical inspection of wafers, i.e., inspection targets, are configured to retain the wafers with a chuck provided in a placement part of a probe device, and carry the wafers. This type of inspection apparatus is known to use a temperature sensor to measure the temperature of a placement surface of the placement part, on which the wafers are to be placed, and adjust the temperature of the placement surface with a heater (temperature adjustment mechanism) in the chuck.

Also, for example, Patent Literature 1 discloses an apparatus including a plurality of temperature measurement resistors (temperature sensors) provided on substrates (wafers) placed on a placement part; and a controller configured to measure resistance values (temperatures) of the temperature measurement resistors of the substrates via a probe and adjust the temperature of a heater of the placement part.

### CITATION LIST

### Patent Literature

Patent Literature 1: Japanese Laid-Open Patent Publication No. 2012-231040

### SUMMARY OF INVENTION

### Problem to be Solved by the Invention

The present disclosure provides a technique of calibrating measurement values of a plurality of temperature sensors provided in a placement part with high accuracy.

### Means For Solving Problem

According to one aspect of the present disclosure, a temperature calibration system includes: an inspection apparatus configured to adjust a temperature of an inspection target placed on a placement part and inspect the inspection target; and a surface thermometer. The temperature calibration system is configured to calibrate a plurality of temperature sensors provided in the placement part. The inspection apparatus includes: a carriage configured to move the placement part in an X-axis direction, a Y-axis direction, and a Z-axis direction; and a controller configured to perform a calibration process to measurement values of the plurality of temperature sensors. The surface thermometer is configured to contact a placement surface of the placement part and detect a surface temperature of the placement surface. The controller is configured to: control the carriage to contact the surface thermometer with a detection position of the placement surface of the placement part; detect the surface temperature of the detection position by the surface thermometer; and calibrate the measurement value of the temperature sensor corresponding to the detection position based on the surface temperature.

### Advantageous Effects of Invention

According to one aspect of the present disclosure, it is possible to calibrate measurement values of a plurality of temperature sensors provided in a placement part with high accuracy.

### BRIEF DESCRIPTION OF DRAWINGS

FIG. 1 is a horizontal cross-sectional view illustrating one example of an inspection apparatus according to a first embodiment.

FIG. 2 is a cross-sectional view of the inspection apparatus of FIG. 1, taken along line II-II.

FIG. 3 is a cross-sectional view of the inspection apparatus of FIG. 1, along a Y-axis direction.

FIG. 4 is a schematic explanatory view illustrating a prober provided in an inspection space.

FIG. 5 is a perspective view illustrating a configuration of a chuck provided in the prober.

FIG. 6 is a schematic plan view illustrating a state in which temperature sensors of the chuck are disposed.

FIG. 7 is an explanatory view illustrating a temperature calibration system.

FIG. 8 is a cross-sectional view illustrating a surface thermometer of a jig and peripheral structures thereof.

FIG. 9 is a block diagram illustrating calibration of the surface thermometer of the temperature calibration system.

FIG. 10 is a block diagram illustrating functional blocks of a prober controller.

FIG. 11 is a first flowchart illustrating a process flow of a temperature calibration method.

FIG. 12 is a second flowchart illustrating the process flow of the temperature calibration method.

FIG. 13 is a schematic plan view of the chuck of the temperature calibration system according to a second embodiment.

FIG. 14 is a flowchart illustrating a process flow of a sensor breakdown detection method.

FIG. 15 is a schematic explanatory view illustrating the inspection apparatus including the temperature calibration system according to a third embodiment.

### DESCRIPTION OF EMBODIMENTS

Hereinafter, embodiments of the present disclosure will be described with reference to the drawings. In the drawings, the same components are given the same symbols, and duplicate description thereof may be omitted.

### First Embodiment

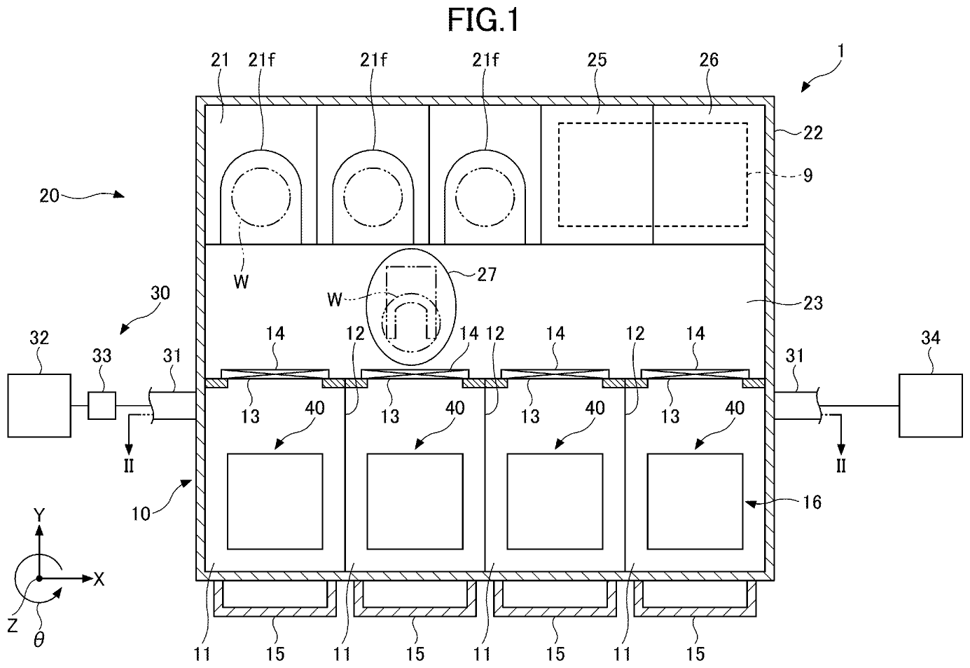

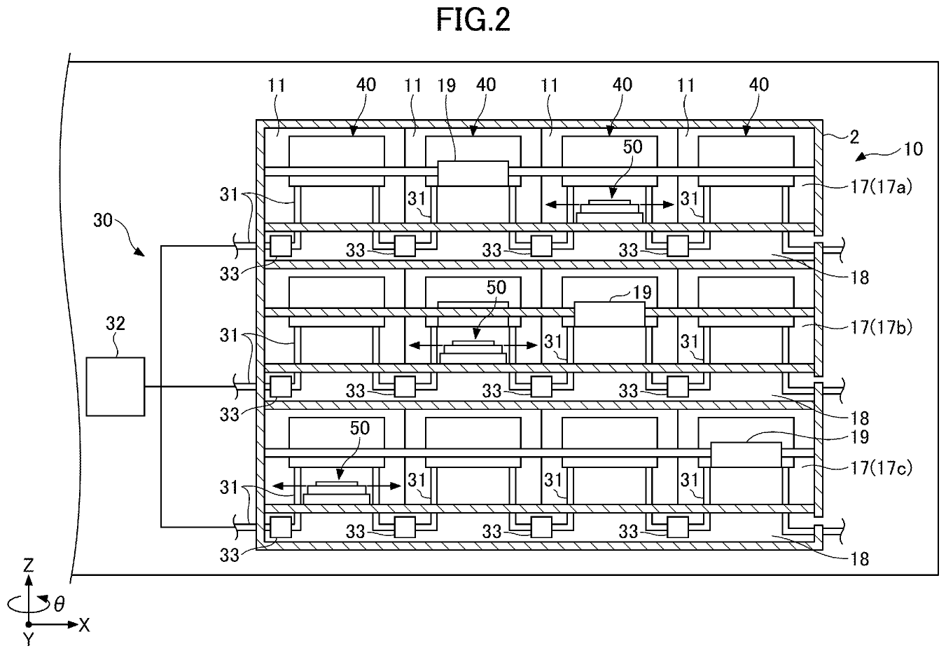

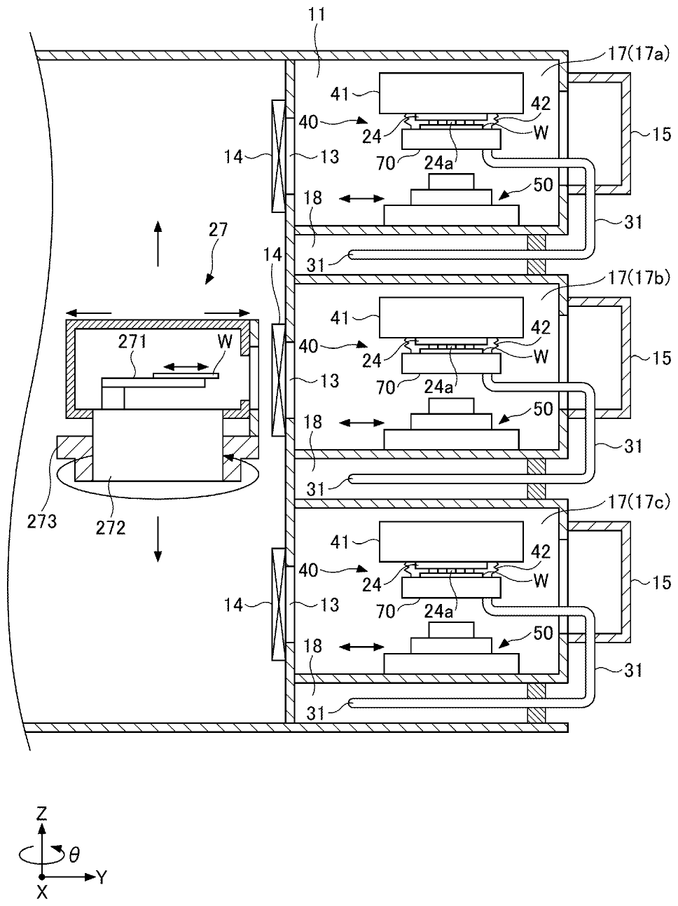

FIG. 1 is a horizontal cross-sectional view illustrating one example of an inspection apparatus 1 according to the first embodiment. FIG. 2 is a cross-sectional view of the inspection apparatus 1 of FIG. 1, taken along line II-II. FIG. 3 is a cross-sectional view of the inspection apparatus 1 of FIG. 1, along the Y-axis direction.

As illustrated in FIG. 1, the inspection apparatus 1 is an apparatus configured to perform an electrical inspection to a semiconductor substrate (wafer W), which is one example of the inspection target. The inspection apparatus 1 is disposed, for example, in a clean room of a factory where the wafer W is produced. This inspection apparatus 1 includes: an inspection part 10 including a plurality of inspection chambers 11; and a loader 20 configured to carry the wafer W to the inspection part 10. The inspection part 10 and the loader 20 are continuous in the Y-axis direction.

The plurality of inspection chambers 11 of the inspection part 10 are separated from each other by partition walls 12. The inspection part 10 includes an inspection unit 40 in each of the inspection chambers 11, and performs an electrical inspection of the wafer W in the inspection unit 40. A carrying port 13 through which the wafer W is carried into and from the loader 20 and a shutter 14 configured to open and close the carrying port 13 are provided on the front surface (positive Y-axis direction) of each of the inspection chambers 11. A cell control unit 15 communicating with each of the inspection chambers 11 and configured to control the inspection unit 40 is provided on the rear surface (negative Y-axis direction) side of each of the inspection chambers 11. The cell control unit 15 includes, for example, a solenoid, a vacuum sensor, an electropneumatic regulator, an E-IOM substrate, a temperature adjuster, and the like (none of these components are illustrated).

The loader 20 includes a stage 21, a carry-in/out part 22, and a carrying chamber 23 that is provided between the inspection part 10 and the carry-in/out part 22. The stage 21 places thereon an FOUP 21f, which is a container configured to store a plurality of wafers W. The carry-in/out part 22 includes a probe card loader 25 configured to carry in/out a probe card 24 (see FIG. 3) and an alignment part 26 configured to align the wafers W. The probe card loader 25 and the alignment part 26 are next to each other along the X-axis direction. A control unit 9 of the inspection apparatus 1 is provided in the carry-in/out part 22. The carrying chamber 23 includes a carrying mechanism 27 configured to carry the wafer W.

The inspection apparatus 1 further includes a coolant part 30 configured to supply a coolant to the inspection part 10 and discharge the coolant from the inspection part 10. The coolant part 30 includes a coolant pipe 31, a coolant output part 32 configured to supply the coolant to the coolant pipe 31, a heat exchanger 33 configured to adjust the temperature of the coolant, and an exhaust heat processor 34 configured to process the coolant discharged from the inspection part 10. The coolant pipe 31 extends between the exterior of the inspection apparatus 1 and the interior of a casing 2 of the inspection apparatus 1 and is connected to the coolant output part 32, the heat exchanger 33, and the exhaust heat processor 34.

As illustrated in FIG. 2, the inspection part 10 includes an inspection chamber row 16 in which four inspection chambers 11 are arranged along the X-axis direction, and the inspection chamber row 16 is arranged in 3 stages along the Z-axis direction (vertical direction). That is, the inspection apparatus 1 includes twelve inspection chambers 11, and the inspection unit 40 for each of the inspection chambers 11.

The inspection chamber row 16 in each of the stages includes four inspection chambers 11 communicated along the X-axis direction by cutting out a part of the partition wall 12, and forms a single approximately sealed inspection space 17. That is, the inspection part 10 has an upper inspection space 17a, a middle inspection space 17b, and a lower inspection space 17c as the inspection chamber row 16 in the Z-axis direction. A coolant piping space 18, in which the coolant pipe 31 of the coolant part 30 is disposed, is formed between the upper inspection space 17a and the middle inspection space 17b, between the middle inspection space 17b and the lower inspection space 17c, or under the lower inspection space 17c. The coolant pipe 31 of the coolant piping space 18 is disposed in each of the upper inspection space 17a, the middle inspection space 17b, and the lower inspection space 17c, and connects the four inspection units 40 in each of the inspection chamber rows 16 in series.

A single prober 50 (stage) movable in the X-axis direction is provided in each of the upper inspection space 17a, the middle inspection space 17b, and the lower inspection space 17c. The prober 50 is provided below each of the inspection units 40 in the inspection chamber row 16, and carries the wafer W to each of the inspection units 40 arranged in the X-axis direction. A single alignment camera 19 movable along the X-axis direction is provided in each of the upper inspection space 17a, the middle inspection space 17b, and the lower inspection space 17c.

As illustrated in FIG. 3, a carrying mechanism 27 of the carrying chamber 23 is movable in the X-axis direction and the Z-axis direction corresponding to the plurality of inspection chambers 11 that are arranged in a matrix. The carrying mechanism 27 includes a carrying arm 271 configured to support the wafer W, a rotary driver 272 configured to rotate the carrying arm 271, and a base 273 configured to support the rotary driver 272.

The carrying mechanism 27 receives the wafer W before inspection from the FOUP 21f and delivers the wafer W to the prober 50 in each of the stages, in response to movement of the carrying arm 271 in the Y-axis direction and rotation of the carrying arm 271 in the e-axis direction. Along with this, the carrying mechanism 27 receives the wafer W after the inspection and returns the inspected wafer W to the FOUP 21f. Further, the carrying mechanism 27 carries the probe card 24 requiring maintenance from each of the inspection units 40 to the probe card loader 25, and carries a new probe card 24 or a probe card 24 that has undergone maintenance, to each of the inspection units 40.

The inspection unit 40 provided in the inspection chamber 11 includes a tester 41, the probe card 24, and a bellows 42. The tester 41 is configured to support the probe card 24 via a support plate (not illustrated) and transmit inspection signals to a plurality of devices formed on the wafer W via a contact block (not illustrated) and a plurality of probes 24a of the probe card 24. The bellows 42 hangs from the support plate so as to enclose the probe card 24, and forms a sealed space including the probe card 24 and the wafer W with the plurality of probes 24a being in contact with the wafer W placed on a chuck 70 of the prober 50. The inspection unit 40 adsorbs the probe card 24 and the chuck 70 to the support plate by vacuuming the sealed space enclosed by the bellows 42 through an unillustrated vacuum line.

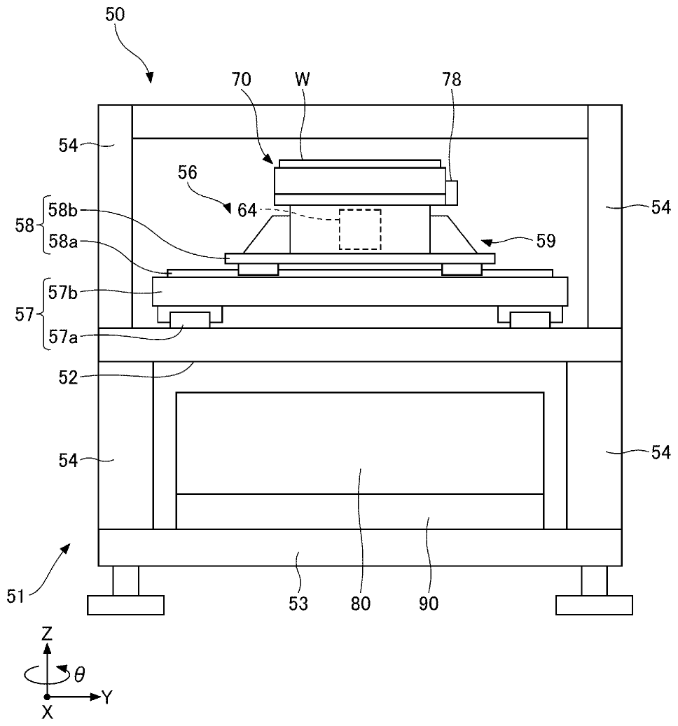

FIG. 4 is a schematic explanatory view illustrating the prober 50 provided in the inspection space 17. As illustrated in FIG. 4, the inspection apparatus 1 includes a frame structure 51 forming the inspection part 10 and supporting the prober 50. The prober 50 disposed in the frame structure 51 carries the wafer W in the X-axis direction, the Y-axis direction, and the Z-axis direction. The prober 50 includes a carriage 56 (an X-axis carrying mechanism 57, a Y-axis carrying mechanism 58, and a Z-axis carrying mechanism 59), the chuck 70, a prober controller 80, and a motor driver 90. The chuck 70 retains the wafer W on an upper surface thereof by an appropriate retaining method (vacuum adsorption, a mechanical chuck, electrostatic adsorption, or the like).

The frame structure 51 has a two-stage structure including an upper base 52 configured to support the carriage 56, a lower base 53 configured to support the prober controller 80 and the motor driver 90, and a plurality of supports 54 provided at the four corners of the upper base 52 and the lower base 53. For example, the space above the upper base 52 is provided in the inspection space 17, and the space between the upper base 52 and the lower base 53 having the prober controller 80 is provided in the coolant piping space 18.

The X-axis carrying mechanism 57 of the carriage 56 includes: a plurality of guide rails 57a fixed to the upper surface of the upper base 52 and extending along the X-axis direction; and an X-axis movable body 57b disposed on each of the guide rails 57a. The X-axis movable body 57b includes an unillustrated X-axis actuator (e.g., a motor, a gear mechanism, or the like) and the X-axis actuator is connected to the motor driver 90. The X-axis movable body 57b reciprocates in the X-axis direction in response to supply of a power from the motor driver 90.

Likewise, the Y-axis carrying mechanism 58 includes: a plurality of guide rails 58a fixed to the upper surface of the X-axis movable body 57b and extending along the Y-axis direction; and a Y-axis movable body 58b disposed on each of the guide rails 58a. The Y-axis movable body 58b also includes an unillustrated Y-axis actuator (e.g., a motor, a gear mechanism, or the like) and the Y-axis actuator is connected to the motor driver 90. The Y-axis movable body 58b reciprocates in the X-axis direction in response to supply of a power from the motor driver 90.

The Z-axis carrying mechanism 59 is disposed at the Y-axis movable body 58b and engages the chuck 70 at an upper part so as to be removable. The Z-axis carrying mechanism 59 is configured to raise and lower the wafer W placed on the chuck 70 by displacing the chuck 70 in the Z-axis direction (vertical direction).

The prober 50, which is configured in this manner, moves the chuck 70 to a desired three-dimensional position by supplying an appropriate power to each of the X-axis carrying mechanism 57, the Y-axis carrying mechanism 58, and the Z-axis carrying mechanism 59 from the motor driver 90 that has received a command from the prober controller 80.

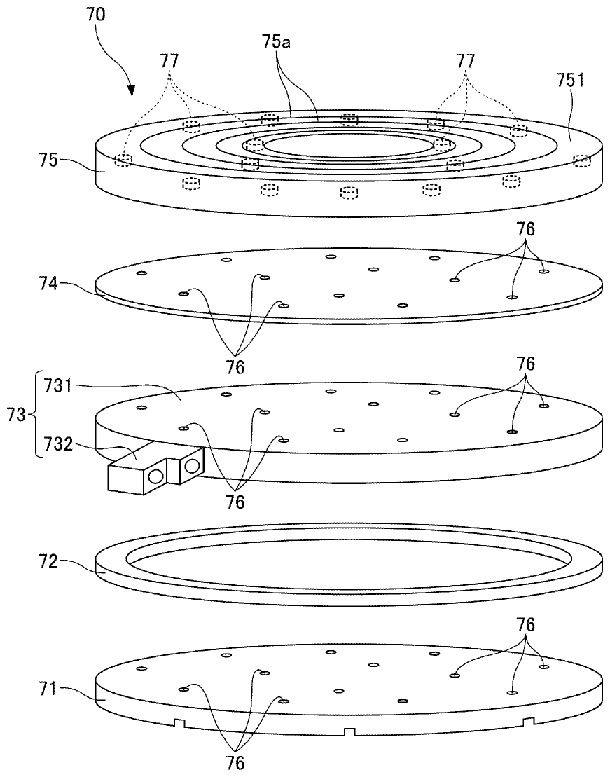

FIG. 5 is a perspective view illustrating a configuration of the chuck 70 provided in the prober 50. As illustrated in FIG. 5, the chuck 70 is formed in a disk shape conforming to the shape of the wafer W to be placed thereon. In addition, the chuck 70 according to the present embodiment has functions of supporting the wafer W through vacuum adsorption and adjusting the temperature of the wafer W. Specifically, the chuck 70 is formed of a stack including a base plate 71, a spacer 72, a temperature adjustment mechanism 73, a uniform heat plate 74, and a top plate 75 in order from the lower side to the upper side in the vertical direction.

The base plate 71 is provided as the lowest layer, and the chuck 70 is attached to the Z-axis carrying mechanism 59. A suction passage (not illustrated) for vacuum adsorption of the wafer W is provided in the base plate 71, and this suction passage is connected to a suction mechanism 64 (see FIG. 4) provided in the Z-axis carrying mechanism 59. The suction passage communicates with a plurality of holes 76 formed in the upper surface of the base plate 71. Each of the holes 76 is also formed through the temperature adjustment mechanism 73 and the uniform heat plate 74, and communicates with a suction recess 75a of the top plate 75. That is, the suction mechanism 64 applies a negative pressure to the top plate 75 through the suction passage and each of the holes 76, thereby retaining the wafer W on the top plate 75.

The spacer 72 is formed in a ring shape running around a periphery facing the outer periphery of the base plate 71, and forms a heat insulating space between the base plate 71 and the temperature adjustment mechanism 73.

The temperature adjustment mechanism 73 includes a disk-shaped jacket 731, and a coolant passage (not illustrated) and a heater (not illustrated) provided in the jacket 731. The jacket 731 includes a coolant port 732 at a predetermined position of the outer periphery thereof. To the coolant port 732, a coolant pipe 31 of a coolant part 30 is connected. The coolant passage communicates with the coolant port 732 and extends in a circular, meandering, or spiral manner along a plane direction (horizontal direction) of the jacket 731. By inflow and outflow of the coolant from the coolant pipe 31 connected to the coolant port 732, the coolant is circulated in the jacket 731, thereby cooling the entire jacket 731.

The heater is, for example, an electric heating wire. The electric heating wire is disposed between the coolant passages in the jacket 731 or above the coolant passages in the jacket 731. The electric heating wire extends in a circular, meandering, or spiral manner along the plane direction of the jacket 731. The heater is electrically connected to a temperature controller (not illustrated) of the prober controller 80. The heater receives supply of an electric power from the prober controller 80, thereby heating the jacket 731. The temperature controller adjusts a temperature of the heater to the target temperature by, for example, a PID control circuit.

The temperature adjustment mechanism 73 individually enables temperature adjustment of a plurality of regions of the chuck 70 in a plan view of the chuck 70. For example, the temperature adjustment mechanism 73 sets four regions into which the flat circular chuck 70 is divided at approximately 90° intervals, and independently arranges the heater and the coolant passage in each of the regions. Thereby, the prober controller 80 can adjust the temperature in each of the four regions by the temperature adjustment mechanism 73.

The uniform heat plate 74 is formed of a material (e.g., ceramic) having an appropriate thermal conductivity. The uniform heat plate 74 uniforms the temperature adjusted by the temperature adjustment mechanism 73 (jacket 731) with respect to the top plate 75 and transmits the adjusted heat to the top plate 75.

The top plate 75 is formed in a disk shape thicker than the uniform heat plate 74, and includes the placement surface 751 on which the wafer W is to be placed. The suction recess 75a is formed in the placement surface 751. The top plate 75 includes a plurality of temperature sensors 77 on an opposite side to the placement surface 751 (rear surface side). The plurality of temperature sensors 77 are configured to measure the temperature of the placement surface 751 (in other words, the temperature of the wafer W placed on the placement surface 751). Note that, when the chuck 70 is configured to electrostatically adsorb the wafer W, the placement surface 751 may be formed in a flat shape.

The prober 50 includes the plurality of temperature sensors 77, and identifies a temperature distribution of the placement surface 751 and enhances accuracy of temperature control by the temperature adjustment mechanism 73. No particular limitation is imposed on a type of the temperature sensors 77, which are preferably, for example, sensors of a resistance temperature detector (RTD) type. The resistance temperature detector may be a thermistor, a thermocouple, an optical temperature sensor, or a semiconductor temperature sensor.

Each of the temperature sensors 77 is electrically connected to a temperature sensor substrate 78 (see FIG. 4) and transmits a measurement value to the temperature sensor substrate 78. The temperature sensor substrate 78 is fixed at a position laterally of a site where the chuck 70 and the Z-axis carrying mechanism 59 are coupled. The temperature sensor substrate 78 is also communicably connected to the prober controller 80. At the time the inspection apparatus 1 inspects the wafer W, the temperature sensor substrate 78 automatically performs switching of measurement among the plurality of temperature sensors 77, and measures the temperature with the switched temperature sensor 77 and transmits a received measurement result to the prober controller 80.

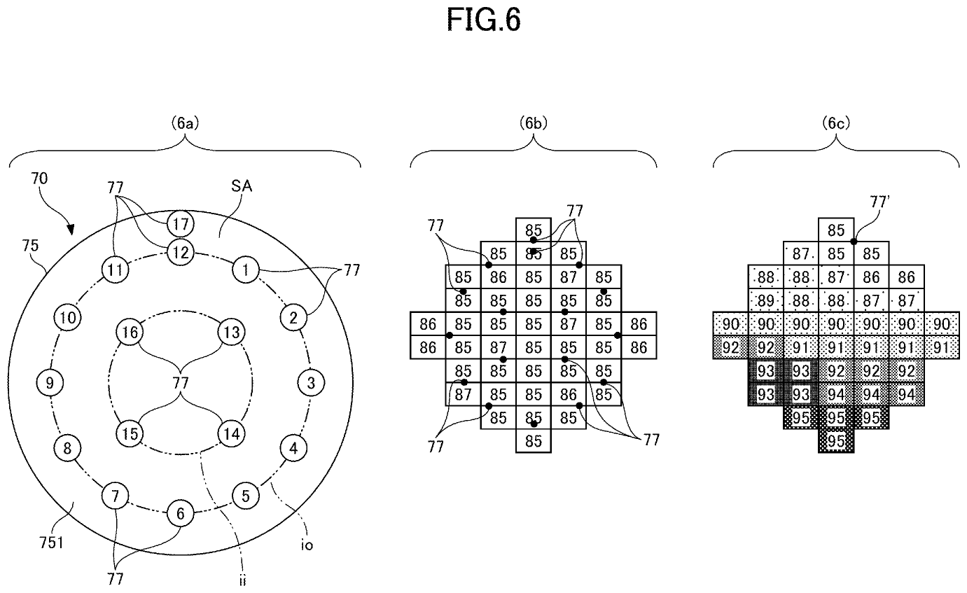

FIG. 6 is a schematic plan view illustrating a state in which the temperature sensors 77 of the chuck 70 are disposed. In FIG. 6, (6a) illustrates an example of arrangement of the temperature sensors 77 according to the present embodiment, (6b) illustrates an example of a temperature distribution of the chuck 70 in the case in which the temperature sensors 77 are used, and (6c) illustrates a referential example of a temperature distribution of the chuck 70 in the case in which a single temperature sensor 77′ is used. As illustrated in (6a), the temperature sensors 77 are arranged in an appropriate number and appropriate installation positions for enabling measurement of the temperature distribution of the entire placement surface 751 of the top plate 75.

As an example, in a plan view of the top plate 75, twelve temperature sensors 77 are provided at equal intervals in a circumferential direction of an imaginary outer circle io and four temperature sensors 77 are provided at equal intervals in a circumferential direction of an imaginary inner circle ii inward of the imaginary outer circle io. Moreover, one temperature sensor 77 is provided at a predetermined position outward of the imaginary outer circle io (at the outer periphery of the top plate 75 on the Y-axis direction side). That is, the top plate 75 includes seventeen temperature sensors 77 in total.

As illustrated in (6c) of FIG. 6, in the configuration in which one temperature sensor 77′ is provided in the chuck 70, this temperature sensor 77′ measures a temperature only around the installation site thereof in the top plate 75. In this case, if the temperature distribution of the placement surface 751 varies, the temperature adjustment mechanism 73 of the prober 50 controls the coolant part 30 or the heater based on the temperature around the installation site of the temperature sensor 77′. For example, the placement surface 751 of the chuck 70 may partially increase in temperature by receiving heat that is generated by the device itself of the wafer W upon inspection. Especially, when the inspection of the wafer W is performed at a high speed, the placement surface 751 tends to partially increase in temperature due to increase in a quantity of the generated heat. Therefore, there is a concern that the accuracy of temperature control by the temperature adjustment mechanism 73 may be reduced in the chuck 70 including one temperature sensor 77′.

Meanwhile, as illustrated in (6b) of FIG. 6, by including the plurality of temperature sensors 77 as in the chuck 70 according to the present embodiment, the prober controller 80 can accurately identify the temperature distribution of the placement surface 751 based on the measurement results of the temperature sensors 77. For example, when the target temperature of the placement surface 751 is set to 85° C., a high-temperature position of the placement surface 751 is measured by the temperature sensors 77 of the temperature sensor substrate 78. By using the measurement values of the temperature sensors 77, the prober controller 80 can effectively control the temperature adjustment mechanism 73 so that the entire placement surface 751 becomes closer to the target temperature.

Of the temperature sensors 77 in (6a) of FIG. 6, the temperature sensors 77 near channel numbers 1, 12, and 17 are the temperature sensors 77 in a site of the chuck 70 in which the temperature is readily stabilized (stable area SA). The temperature being readily stabilized means that responsiveness to temperature adjustment by the temperature adjustment mechanism 73 is faster (higher) than other sites because of the presence of sites near an inlet of the coolant in the coolant passage and near an input of a heater controlled by PID. That is, the temperature of the temperature sensor substrate 78 more readily monitors the temperature of the placement surface 751 by first detecting the temperature of the temperature sensor 77 in the stable area SA (e.g., channel number 1) among the temperature sensors 77 for temperature adjustment by the temperature adjustment mechanism 73.

As a matter of course, no particular limitation is imposed on the number and the installation positions of the temperature sensors 77 of the chuck 70 as long as two or more temperature sensors 77 are provided and the installation positions thereof are appropriately determined in accordance with, for example, the positions of the coolant passage and the heater. The types of the temperature sensors 77 provided in the chuck 70 may be identical to or different from each other.

The prober controller 80 is connected to the control unit 9 of the inspection apparatus 1, and controls the operation of the prober 50 based on the command of the control unit 9. The prober controller 80 includes, for example, a main controller configured to control the operation of the entire prober 50, a PLC configured to control the operation of the carriage 56, a temperature controller configured to control the temperature adjustment mechanism 73, an illumination controller (not illustrated), and a power supply unit (not illustrated). A board including a built-in computer for a prober can be used as the main controller of the prober controller 80. The board includes unillustrated one or more processors, memories, input/output interfaces, electronic circuits, and the like. The one or more processors are a combination of one or more of CPUs, ASICs, FPGAs, circuits formed of a plurality of discrete semiconductors, and the like, and execute and process programs and recipes stored in the memory. The memory includes a nonvolatile memory and a volatile memory, and forms a storage of the prober controller 80.

After the chuck 70 in the prober 50 receives the wafer W from the carrying mechanism 27, the prober controller 80 moves the carriage 56 in the horizontal direction (X-Y axis direction) and performs alignment so that the wafer W faces the probe card 24 of the predetermined inspection unit 40. After alignment, the prober controller 80 raises the chuck 70 by the prober 50, and contacts the wafer W with a probe 24a of the probe card 24. While maintaining the contact state between the wafer W and the probe 24a, the control unit 9 of the inspection apparatus 1 vacuums the sealed space enclosed by the bellows 42, thereby adsorbing the chuck 70 to the support plate. In this state, the control unit 9 starts an electrical inspection by the tester 41. After completion of the inspection by the tester 41, the prober controller 80 moves the inspected wafer W downward and horizontally in a motion reverse to the above motion, thereby returning the wafer W to the carrying mechanism 27.

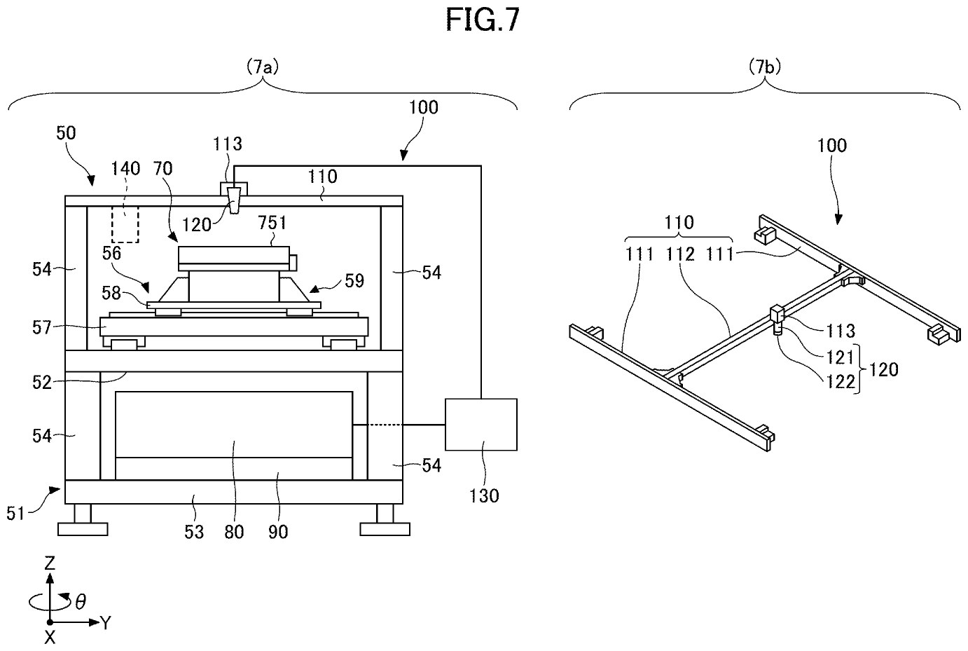

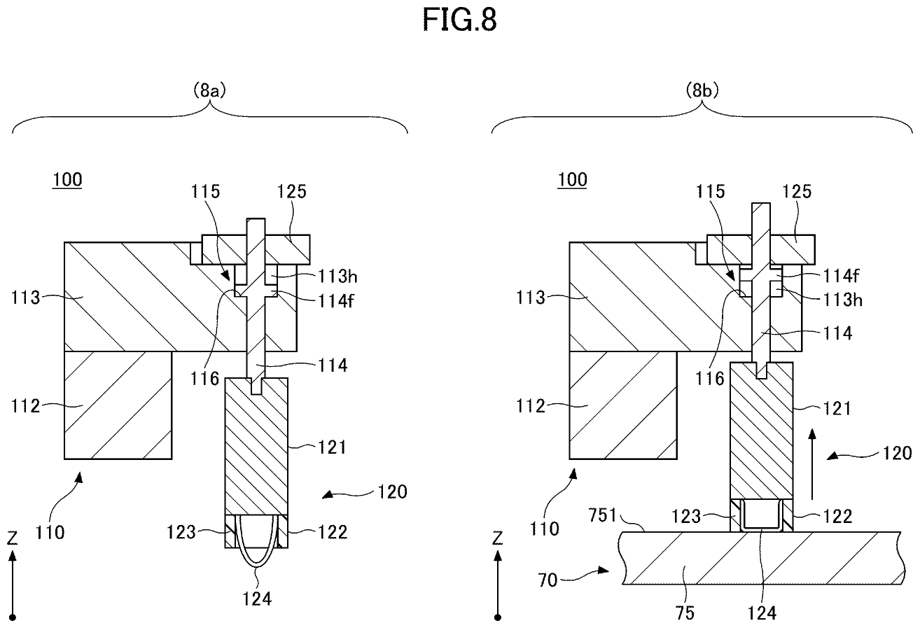

The inspection apparatus 1 needs to calibrate the plurality of temperature sensors 77 provided in the chuck 70. Next, a temperature calibration system 100 configured to calibrate each of the temperature sensors 77 will be described with reference to FIG. 7 and FIG. 8. FIG. 7 is an explanatory view illustrating the temperature calibration system 100. In FIG. 7, (7a) is a schematic side view of the system, and (7b) is a perspective view illustrating a jig 110. FIG. 8 is a cross-sectional view illustrating a surface thermometer 120 of the jig 110 and peripheral structures thereof. In FIG. 8, (8a) illustrates a state in which the surface thermometer 120 is not in contact with the placement surface 751, and (8b) illustrates a state in which the surface thermometer 120 is in contact with the placement surface 751.

The temperature calibration system 100 according to the present embodiment uses the prober 50 using the measurement values of the temperature sensors 77 in order to calibrate the measurement values obtained by the temperature sensors 77. In addition to the prober 50, the temperature calibration system 100 includes: the jig 110 including the surface thermometer 120 to be fixed to the frame structure 51 and configured to detect the temperature of the placement surface 751 of the chuck 70; and a data logger 130 configured to record detection results of the surface thermometer 120.

The jig 110 places the surface thermometer 120 above the chuck 70. The jig 110 according to the present embodiment is formed in an H shape in a plan view thereof, by including: a pair of bars 111 that can be placed on a plurality of supports 54 of the frame structure 51; and a bridge 112 that bridges between center portions of the pair of bars 111 in extending directions of the pair of bars 111. The jig 110 is, for example, a metal frame of aluminum or the like. The surface thermometer 120 is fixed to a center portion of the bridge 112 of the jig 110 in an extending direction of the bridge 112.

The jig 110 includes a fixing block 113 in the bridge 112, and the fixing block 113 is configured to fix the surface thermometer 120. The fixing block 113 is attached to the jig 110 so as to be adjustable in a position thereof along a plane direction (horizontal direction) of the frame structure 51. The fixing block 113 supports the surface thermometer 120 via a supporting bar 114 at a portion projecting laterally from the bridge 112.

The fixing block 113 and the supporting bar 114 form a relief structure 115 configured to retain the surface thermometer 120 so as to be displaceable along the vertical direction (Z-axis direction). The relief structure 115 has a function of relieving the pressing force upon contact of the surface thermometer 120 with the placement surface 751 by permitting the surface thermometer 120 to move upward relative to the jig 110 while restricting the horizontal displacement of the surface thermometer 120 relative to the jig 110. For example, the fixing block 113 has a through-hole 113h through which the supporting bar 114 is extended, and a step 116 is formed on the inner peripheral surface forming the through-hole 113h. Meanwhile, the supporting bar 114 includes a flange 114f configured to be caught by the step 116. An upper part of the through-hole 113h is formed on the inner-diameter side on which the flange 114f is movable, and a pull-out preventing member 125 is provided. The supporting bar 114 is permitted to move upward of the fixing block 113 by the through hole 113h, and is prevented from falling downward of the fixing block 113 by engagement between the flange 114f and the step 116.

The surface thermometer 120 is connected to the lower end of the fixing block 113, and is suspended along the vertical direction by the jig 110. The surface thermometer 120 includes: a cylindrical casing 121 extending in the vertical direction; and a detector 122 provided under the casing 121. The detector 122 includes: a contact body 123 that is connected to the casing 121; and a detection element 124 that directly contacts the placement surface 751 of the chuck 70 within the contact body 123.

The contact body 123 is formed of a resin material, such as polyimide, and a lower end surface thereof facing the placement surface 751 is formed in a flat shape. The contact body 123 has an annular (cylindrical) shape that is continuous with the outer peripheral surface of the casing 121 so as to be flush therewith. A planarly circular cavity for arrangement of the detection element 124 is provided in the contact body 123. The contact body 123 has a heat insulation higher than that of the detection element 124, and reduces release of heat and enhances detection accuracy of the detection element 124.

The detection element 124 may be a K-type thermocouple formed in a thin-plate shape. Both ends of the detection element 124 are fixed to a surface of the casing 121 that is coupled to the contact body 123. The detection element 124 is formed in a dome shape in which a middle portion thereof is curved downward from both of the ends. The plate thickness of the detection element 124 is much thinner (e.g., 1/10 or less) than the thickness of the contact body 123 along a radial direction thereof. The detection element 124 that is formed to be thin has a small heat capacity, and a faster heat responsiveness upon contact with the placement surface 751.

When a portion of the detection element 124 that projects from the lower end surface of the contact body 123 contacts the placement surface 751 of the chuck 70, the detection element 124 readily elastically deforms in upward and lateral directions and plane-contacts the placement surface 751. In a state in which the contact body 123 is in contact with the placement surface 751, the detection element 124 can always contact the placement surface 751 in the same contact area. That is, the detection element 124 can detect the temperature in the same detection manner even if the temperature detection is performed multiple times (reproducibility is ensured).

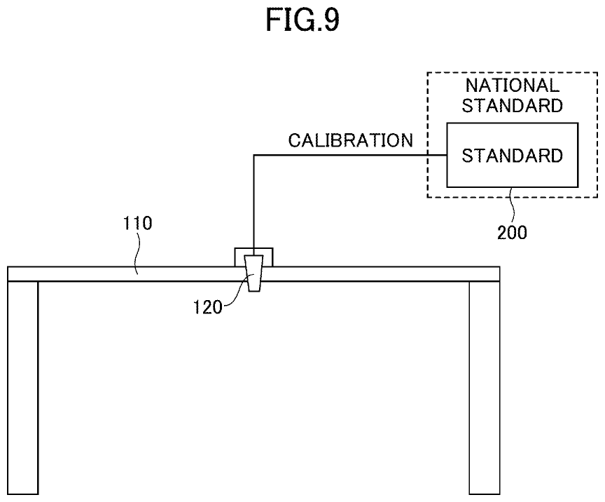

FIG. 9 is a block diagram illustrating calibration of the surface thermometer 120 of the temperature calibration system 100. As illustrated in FIG. 9, the surface thermometer 120 according to the present embodiment is calibrated for a temperature detected by the surface thermometer 120, based on a standard 200 that is previously calibrated so as to conform to a national standard (international standard). For example, the surface thermometer 120 is connected to a standard 200 of a calibration service organization that regularly performs calibration so as to conform to the national standard. Then, the surface thermometer 120 is calibrated so that a calibration curve of the temperature of the surface thermometer 120 coincides with the calibration curve of the temperature of the standard 200 (traces to the national standard).

Because the surface thermometer 120 provided in the jig 110 is one for the plurality of temperature sensors 77 provided in the chuck 70, the calibration of the surface thermometer 120 itself by the standard 200 can be performed in a short time. In addition, the calibration of the surface thermometer 120 is preferably performed on a regular basis (e.g., about once a year). The surface thermometer 120 calibrated in this manner ensures the same temperature compensation as the standard 200 (i.e., the national standard).

The data logger 130 is a computer including a processor, a memory, and input/output interfaces (none of these components are illustrated) and stores the surface temperature detected by the surface thermometer 120. The memory includes a volatile memory and a nonvolatile memory (storage media, such as computer storage media, flexible disks, compact disks, hard disks, magneto-optical disks, and memory cards) and forms a storage of the data logger 130. The data logger 130 is connected to the surface thermometer 120 and to the prober controller 80.

The temperature calibration system 100 calibrates each of the temperature sensors 77 upon shipment of the prober 50 (inspection apparatus 1). In this calibration, the temperature calibration system 100 contacts the surface thermometer 120 with the detection position of the placement surface 751 overlapping the plurality of temperature sensors 77, thereby detecting the surface temperature of the placement surface 751. The data logger 130 obtains, from the prober controller 80, the position information of the detection position of the placement surface 751 facing the surface thermometer 120. In addition, the data logger 130 obtains the surface temperature from the surface thermometer 120 and stores, in the memory, the position information, the surface temperature, and the time information of the detection position in association with each other.

The prober controller 80 obtains, as calibration information, the position information, the surface temperature, and the time information of the detection position accumulated in the data logger 130. By using the calibration information, the prober controller 80 calibrates each of the temperature sensors 77 of the chuck 70. The temperature calibration system 100 may not include the data logger 130 and may be configured such that the prober controller 80 directly obtains the surface temperature detected by the surface thermometer 120. By performing calibration of each of the temperature sensors 77, the prober controller 80 can conform the measurement value of the predetermined temperature sensor 77 to the surface temperature detected by the surface thermometer 120.

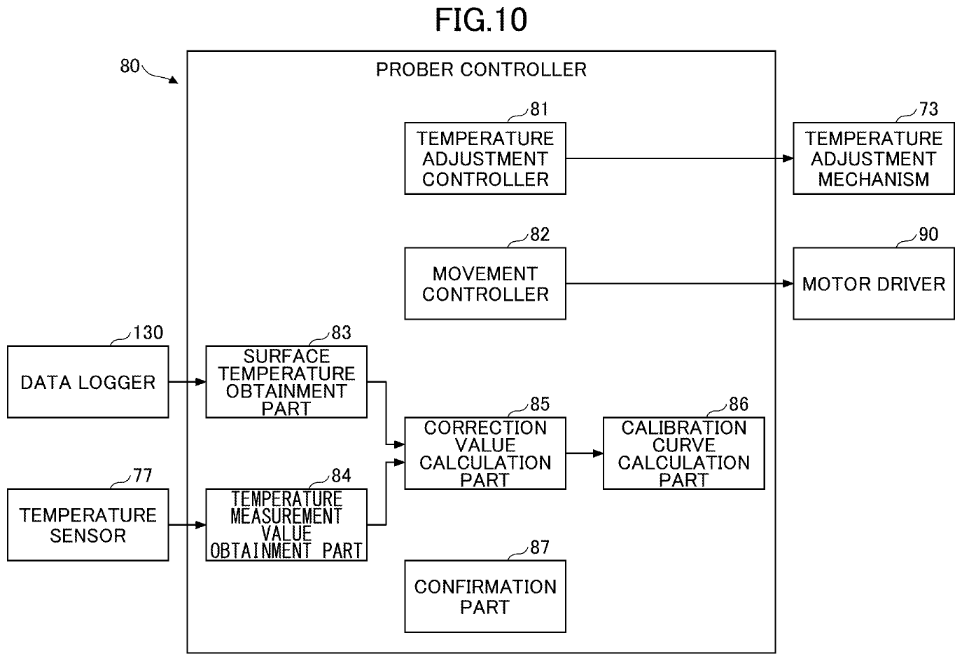

FIG. 10 is a block diagram illustrating functional blocks of the prober controller 80. In the calibration of each of the temperature sensors 77, as illustrated in FIG. 10, the prober controller 80 includes a temperature adjustment controller 81, a movement controller 82, a surface temperature obtainment part 83, a temperature measurement value obtainment part 84, a correction value calculation part 85, a calibration curve calculation part 86, and a confirmation part 87.

The temperature adjustment controller 81 controls the temperature adjustment mechanism 73 (the coolant part 30, the heater) of the prober 50, thereby setting the temperature of the chuck 70 as a standard temperature set in the calibration of each of the temperature sensors 77. No particular limitation is imposed on the standard temperature. However, three temperatures of −55° C., 25° C., and 150° C. are exemplified.

The movement controller 82 is configured to output a control command to the motor driver 90 and control the operation of the carriage 56 of the prober 50 via the motor driver 90. Upon the calibration of each of the temperature sensors 77, the movement controller 82 contacts the surface thermometer 120 with the detection position of the placement surface 751 overlapping the predetermined temperature sensor 77 among the temperature sensors 77. For example, the movement controller 82 previously has the position information of each of the temperature sensors 77, and calculates a moving distance and a moving direction from one of the temperature sensors 77 to another temperature sensor 77 based on the position information and controls the carriage 56 so as to conform to the moving distance and the moving direction that are calculated.

When calibrating each of the temperature sensors 77, preferably, the movement controller 82 sequentially performs a calibration process to the temperature sensors 77 that are located closer to each other. For example, the movement controller 82 performs temperature calibration of the temperature sensors 77 (detection of the temperature of the placement surface 751) in the order of the channel numbers assigned to the temperature sensors 77 in (6a) of FIG. 6. Thereby, the moving time of the prober 50 in the temperature calibration method can be shortened, and the time required for calibration can be shortened.

Referring back to FIG. 10, the surface temperature obtainment part 83 is configured to obtain, from the data logger 130, the surface temperature of each of the temperature sensors 77 detected by the surface thermometer 120, and store the surface temperature in the memory. For example, when the surface thermometer 120 ends detection for one standard temperature at the detection positions of all of the temperature sensors 77, the surface temperature obtainment part 83 obtains, from the data logger 130, calibration information (the surface temperature and the time information of each of the detection positions).

Meanwhile, the temperature measurement value obtainment part 84 is configured to obtain the temperature measured by each of the temperature sensors 77 (measurement value) and store the measurement value in the memory in association with the position information, the time information, and the like of each of the temperature sensors 77. Especially, the temperature measurement value obtainment part 84 obtains the operation state of the movement controller 82, and measures the temperature of the predetermined temperature sensor 77 in synchronization with the timing when the surface thermometer 120 detects the surface temperature of the detection position. Thereby, the measurement value of the predetermined temperature sensor 77 stored in the memory and the surface temperature of the surface thermometer 120 can be treated as the value detected at the same timing.

The correction value calculation part 85 is configured to calculate, as a correction value, the difference between: the measurement value of the predetermined temperature sensor 77 obtained by the temperature measurement value obtainment part 84; and the surface temperature of the predetermined temperature sensor 77 obtained from the data logger 130. The correction value calculation part 85 performs the calculation of the correction value for all of the temperature sensors 77 and stores the calculated value, in the memory, as the correction value corresponding to each of the temperature sensors 77. The correction value is stored so as to be associated with the measurement value of each of the temperature sensors 77. That is, the value obtained by addition of the correction value associated with the measurement value of the temperature sensor 77 becomes a calibration value of the temperature sensor 77 at a predetermined standard temperature.

The calibration curve calculation part 86 is configured to calculate a calibration curve for each of the temperature sensors 77 based on the measurement value and the correction value stored in the memory, when the correction value calculation part 85 calculates the correction value for each of the standard temperatures. The calibration curve calculation part 86 also calculates the calibration curve for all of the temperature sensors 77 and stores, in the memory, the calculated calibration curve for each of the temperature sensors 77.

For example, the calibration curve for each of the temperature sensors 77 is calculated based on a linear function having an appropriate slope and an appropriate intercept obtained based on a plurality of calibration values. The calibration curve is preferably calculated by two functions: a linear function of from −55° C. through 25° C. and a linear function of from 25° C. through 150° C. Thereby, the prober controller 80 has a highly accurate calibration curve for each of the temperature sensors 77, and can accurately measure a temperature distribution of the placement surface 751 when the inspection apparatus 1 inspects the wafer W. The calibration curve of the temperature sensor 77 may be calculated in accordance with characteristics of the sensor, and may be another function, such as a quadratic function or the like.

The confirmation part 87 is configured to re-detect the surface temperature of each of the temperature sensors 77 by the surface thermometer 120 and set the re-detected temperature as a check temperature, and confirm the calibration result by comparing the calibration value, obtained in the correction value calculation part 85, with the check temperature. The operations of the components in the confirmation part 87 are basically the same as the operations of the components at the time of calibration, and details thereof will be described below.

When the inspection apparatus 1 is operated after calibration of the temperature sensors 77, the prober controller 80 obtains a measurement value of each of the temperature sensors 77 based on the calibration curve set for each of the temperature sensors 77.

Thereby, the prober controller 80 can further accurately control the temperature adjustment mechanism 73, and can appropriately adjust the temperature of the placement surface 751.

The temperature calibration system 100 according to the present embodiment is formed as described above, and operation thereof (temperature calibration method) will be described below.

Upon the initial stage in which the inspection apparatus 1 is installed in a factory or upon subsequent maintenance thereof, an operator performs a temperature calibration method of calibrating the temperature sensors 77 of the prober 50. In performing the temperature calibration method, the operator first attaches the jig 110 to the frame structure 51 of the prober 50. Thereby, the surface thermometer 120 of the jig 110 is disposed at a position that can face the placement surface 751 of the chuck 70.

After attachment of the jig 110, the operator operates the control unit 9 (an unillustrated user interface) of the inspection apparatus 1 to perform the temperature calibration method. Thereby, after receiving a command to perform the temperature calibration method from the control unit 9, the prober controller 80 starts a process of the temperature calibration method.

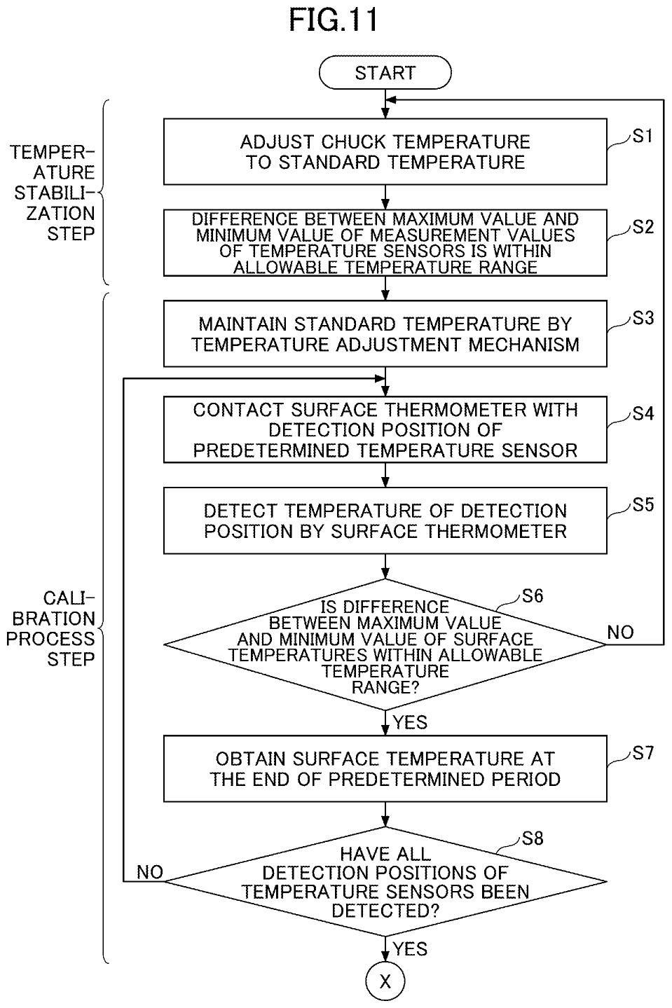

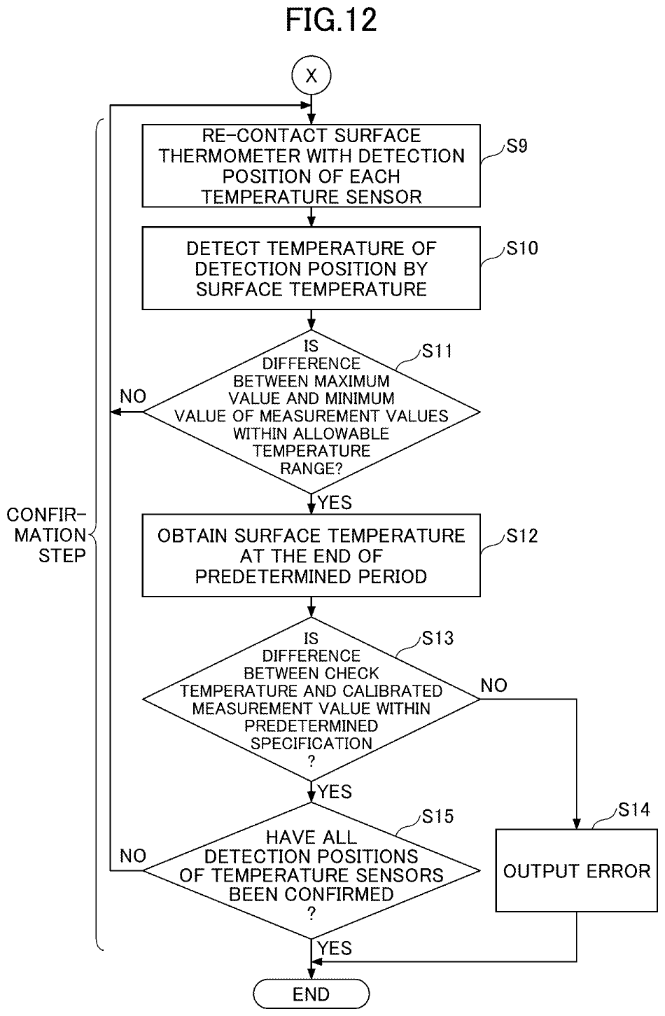

FIG. 11 is a first flowchart illustrating the process flow of the temperature calibration method. FIG. 12 is a second flowchart illustrating the process flow of the temperature calibration method. As illustrated in FIG. 11 and FIG. 12, the prober controller 80 sequentially performs a temperature stabilization step, a calibration process step, and a confirmation step in the temperature calibration method. The prober controller 80 repeatedly performs the process flows illustrated in FIG. 11 and FIG. 12 for each of the above three standard temperatures (−55° C., 25° C., and 150° C.) and eventually obtains a calibration curve of each of the temperature sensors 77.

Specifically, after starting the temperature calibration method, the prober controller 80 first controls the temperature adjustment mechanism 73 by the temperature adjustment controller 81 as the temperature stabilization step, and adjusts the temperature of the chuck 70 to the standard temperature in the present process flow (step S1). For example, the prober controller 80 sets one of the standard temperatures to the target temperature for adjustment by the temperature adjustment mechanism 73.

Subsequently, the prober controller 80 measures the temperature by the predetermined temperature sensor 77 over a predetermined stabilization period, and sets a state in which the difference between the maximum value and the minimum value of the measurement values during the stabilization period is within an allowable temperature range (step S2). The stabilization period may be, for example, from 5 minutes through 10 minutes. As the predetermined temperature sensor 77 that monitors the temperature, the temperature sensor 77 in the stable area SA in which the temperature is readily stabilized, is preferable. The present embodiment uses the measurement value of the temperature sensor 77 of channel number 1 in (6a) of FIG. 6. The allowable temperature range may be, for example, within +0.5° C. Thereby, the temperature of the placement surface 751 is stabilized at the end of the temperature stabilization step.

In the calibration process step after the temperature stabilization step, the prober controller 80 performs control to maintain the standard temperature by the temperature adjustment mechanism 73 (step S3). Then, the prober controller 80 controls the carriage 56, for example, so as to be in accordance with the numerical order of the temperature sensors 77 as illustrated in (6a) of FIG. 6 by the movement controller 82, and contacts the surface thermometer 120 with the detection position of the placement surface 751 overlapping the predetermined temperature sensor 77 (step S4).

In the control of the carriage 56, the prober controller 80 first moves the chuck 70 in the horizontal direction (X-Y-axis direction) to face the detection position of the predetermined temperature sensor 77 and the detection element 124 of the surface thermometer 120 each other. Then, the prober controller 80 moves the chuck 70 upward (positive Z-axis direction) to contact the placement surface 751 with the detection element 124 of the surface thermometer 120. At this time, the prober controller 80 continues to move the chuck 70 upward and relatively displaces the surface thermometer 120 upward relative to the fixing block 113 even after the lower end surface of the contact body 123 of the surface thermometer 120 contacts the placement surface 751. Thereby, the shape of the detection element 124 of the surface thermometer 120 is changed so as to contact a predetermined range of the placement surface 751 (see (8b) of FIG. 8b).

Upon completion of the movement of the prober 50, the temperature of the detection position is detected by the surface thermometer 120, and the data logger 130 receives the surface temperature from the surface thermometer 120 (step S5). At this time, the data logger 130 also obtains, from the prober controller 80, the position information of the detection position of the placement surface 751 facing the surface thermometer 120 (the installation position of the temperature sensor 77) and stores the position information of the detection position in association with the surface temperature.

The prober controller 80 also obtains the surface temperature of the surface thermometer 120 via the data logger 130 by the surface temperature obtainment part 83, and monitors whether or not the difference between the maximum value and the minimum value of the surface temperatures is within the allowable temperature range (e.g., ±0.5° C.) over a predetermined period (step S6). No particular limitation is imposed on the predetermined period for which the surface temperature is monitored, which however may be set to be, for example, from several tens of seconds through several minutes. When the difference between the maximum value and the minimum value exceeds the allowable temperature range (step S6: NO), this is indication that the temperature adjustment by the temperature adjustment mechanism 73 is no longer stable. Therefore, for example, the prober controller 80 stops the calibration process step and re-starts the process flow from step S1.

Meanwhile, when the difference between the maximum value and the minimum value is within the allowable temperature range (step S6: YES), this is indication that the temperature adjustment by the temperature adjustment mechanism 73 is stable. Therefore, in step S7, the prober controller 80 obtains the surface temperature of the surface thermometer 120 at the end of the predetermined period by the surface temperature obtainment part 83, and obtains the measurement value of the predetermined temperature sensor 77 corresponding to the detection position by the temperature measurement value obtainment part 84.

Furthermore, the correction value calculation part 85 of the prober controller 80 calculates a difference (correction value) between the measurement value of the predetermined temperature sensor 77 and the surface temperature of the surface thermometer 120, and stores the difference in the memory. At the standard temperature of this process flow, the measurement value of the predetermined temperature sensor 77 matches the surface temperature of the surface thermometer 120 by addition of the calculated correction value.

After completion of step S7, the prober controller 80 moves the chuck 70 downward (negative Z-axis direction) to separate the detection element 124 of the surface thermometer 120 from the placement surface 751. Subsequently, the prober controller 80 determines whether or not all of the detection positions of the temperature sensors 77 in the placement surface 751 have been detected by the surface thermometer 120 (step S8). When the detection of the temperature sensors 77 is not completed (step S8: NO), the prober controller 80 returns the process flow to step S4 and repeats the same process flow. Meanwhile, when calibration values (correction values) are obtained for all of the detection positions of the temperature sensors 77, the calibration process step is ended and the process flow proceeds to the confirmation step as illustrated in FIG. 12.

In the confirmation step, the confirmation part 87 controls the carriage 56 of the prober 50 by the movement controller 82, thereby re-contacting the surface thermometer 120 with the detection position of each of the temperature sensors 77 in the placement surface 751 (step S9). Thereby, the surface thermometer 120 detects the temperature of the detection position as the check temperature (step S10).

The confirmation part 87 continuously obtains the measurement value of the temperature sensor 77 at the detection position by the temperature measurement value obtainment part 84, and monitors whether or not the difference between the maximum value and the minimum value of the measurement values is within an allowable temperature range (e.g., ±0.5° C.) over a predetermined period (step S11). The measurement value of the temperature sensor 77 reflects the calibration value (correction value) in step S7. When the difference between the maximum value and the minimum value of the measurement values exceeds the allowable temperature range (step S6: NO), this is indication that the temperature adjustment by the temperature adjustment mechanism 73 is no longer stable. Therefore, for example, the confirmation part 87 stops the confirmation step and re-starts the process flow from step S9.

Meanwhile, when the difference between the maximum value and the minimum value is within the allowable temperature range (step S11: YES), this is indication that the temperature adjustment by the temperature adjustment mechanism 73 is stable. Therefore, in step S12, the confirmation part 87 obtains the surface temperature of the surface thermometer 120 at the end of the predetermined period by the surface temperature obtainment part 83. Moreover, the confirmation part 87 compares the surface temperature (check temperature) at the detection position with the measurement value of the calibrated temperature sensor 77, and determines whether or not the difference between the check temperature and the calibrated measurement value is within a predetermined specification (spec.) (step S13). When the difference between the check temperature and the calibrated measurement value exceeds the specification, the process flow proceeds to step S14 to output an error via the user interface. This specification may be set based on the standard (error range) of the temperature sensor 77.

Meanwhile, when the difference between the check temperature and the calibrated measurement value is within a range of the specification, a normal calibration result of the temperature sensor 77 is identified, and the process flow proceeds to step S15. The confirmation part 87 determines whether or not all of the detection positions of the temperature sensors 77 have been confirmed (step S15). When the confirmation of the temperature sensors 77 is not completed (step S15: NO), the confirmation part 87 returns the process flow to step S9 and repeats the same process flow. Meanwhile, when the confirmation is completed for all of the detection positions of the temperature sensors 77 (step S15: YES), the confirmation step is ended.

Then, when the calibration curve calculation part 86 of the prober controller 80 performs the above process flow (calibration of the measurement values of the temperature sensors 77) with respect to the three standard temperatures, the calibration curves of the temperature sensors 77 are calculated based on the calibration values at the three points. Thereby, the prober controller 80 can adjust the measurement values of the temperature sensors 77 to the surface temperature detected by the surface thermometer 120, and consequently, can calibrate the measurement values of the temperature sensors 77 so as to conform to the national standard.

Note that the temperature calibration system 100 and the temperature calibration method are not limited to the above embodiments, but may have various modified examples. For example, the temperature calibration system 100 may include a position detector 140 configured to detect the position of the surface thermometer 120 or the position of the chuck 70, as illustrated with a dotted line in (7a) of FIG. 7. Examples of the position detector 140 include: a camera configured to capture the surroundings of the surface thermometer 120; and a displacement meter configured to measure the distance of the surface thermometer 120 or the distance of the chuck 70 (e.g., a laser displacement meter). The position detector 140 enables the prober controller 80 to accurately identify the relative position between the placement surface 751 of the chuck 70 and the surface thermometer 120. Therefore, the prober controller 80 can further accurately move the prober 50 relative to the surface thermometer 120 by feeding back the relative position, and can more reliably contact the surface thermometer 120 with the detection position of each of the temperature sensors 77.

Also, for example, the temperature calibration system 100 is not limited to a configuration in which the placement surface 751 is moved relative to the surface thermometer 120 by the carriage 56 (placement surface 751) of the prober 50, but may also be configured such that the surface thermometer 120 is moved relative to the placement surface 751.

### Second Embodiment

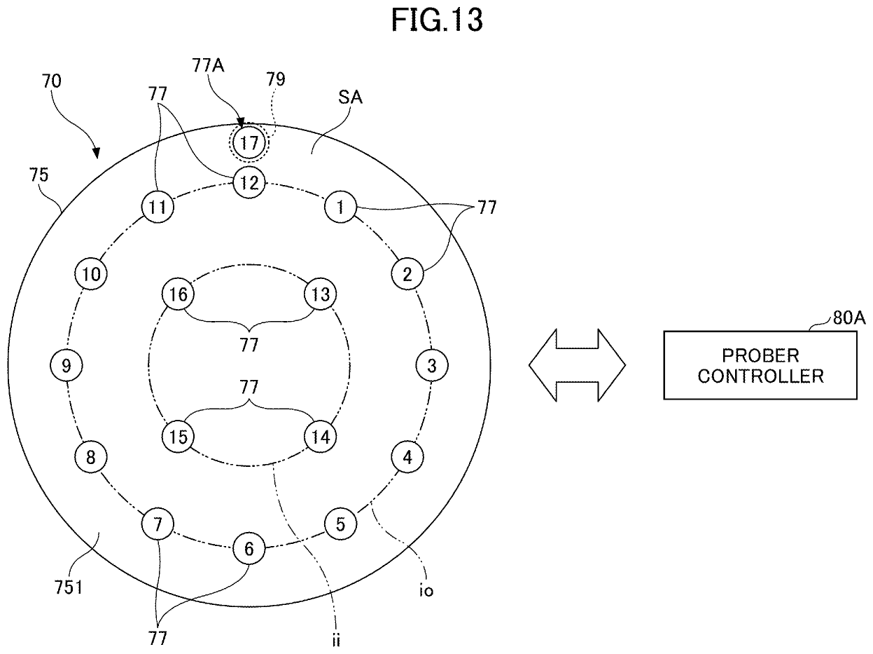

FIG. 13 is a schematic plan view of the chuck 70 of the temperature calibration system 100 according to the second embodiment. As illustrated in FIG. 13, the temperature calibration system 100 according to the second embodiment uses a portion (one or more) of the temperature sensors 77 as a standard sensor 77A for detecting breakdown of the other temperature sensors 77. The standard sensor 77A is preferably the temperature sensor 77 in the stable area SA in which the temperature is readily stabilized. For example, the temperature sensor 77 of channel number 1 or 17 in FIG. 13 is preferably used. In the present embodiment, the temperature sensor 77 of channel number 17 is used as the standard sensor 77A.

The temperature sensor 77 used as the standard sensor 77A is preferably a sensor that is located in the area in which the temperature is readily stabilized and whose specifications, such as heat resistance, measurement accuracy (allowable error range), and the like are superior to the specifications of the other temperature sensors 77. For example, the standard sensor 77A is preferably a temperature measurement resistor with a platinum resistance element that is more accurate than the temperature measurement resistor (e.g., a thermistor) of the other temperature sensors 77.

Preferably, the standard sensor 77A is housed in a protection tube 79 and placed on the rear surface of the top plate 75, and the sensor is protected from the atmosphere around the prober 50. The protection tube 79 is formed of stainless steel (SUS304) or the like. The standard sensor 77A provided in the protection tube 79 is highly resistant to foreign matter compared to the top plate 75 around the protection tube 79. In other words, the standard sensor 77A is less prone to abnormality among the temperature sensors 77.

When the inspection apparatus 1 is installed or is subjected to maintenance, the standard sensor 77A is also temperature-calibrated by the surface thermometer 120. Thereby, it is possible to preform temperature measurement according to the national standard (trace to the national standard). Therefore, the standard sensor 77A can accurately measure the temperature of the placement surface 751 at the detection position, and also has high reliability and serves as a reference with respect to the other temperature sensors 77.

Upon operation of the inspection apparatus 1, a prober controller 80A according to the second embodiment uses the standard sensor 77A to perform a process for detecting the breakdown of the other (16) temperature sensors 77. That is, the inspection apparatus 1 regularly or if necessary performs a sensor breakdown detection method for determining normality or abnormality of the temperature sensors 77. The sensor breakdown detection method is performed using the standard sensor 77A calibrated by the temperature calibration method. In this sense, the sensor breakdown detection method is a process related to the temperature calibration method of the present disclosure. In the following, the sensor breakdown detection method will be described in detail.

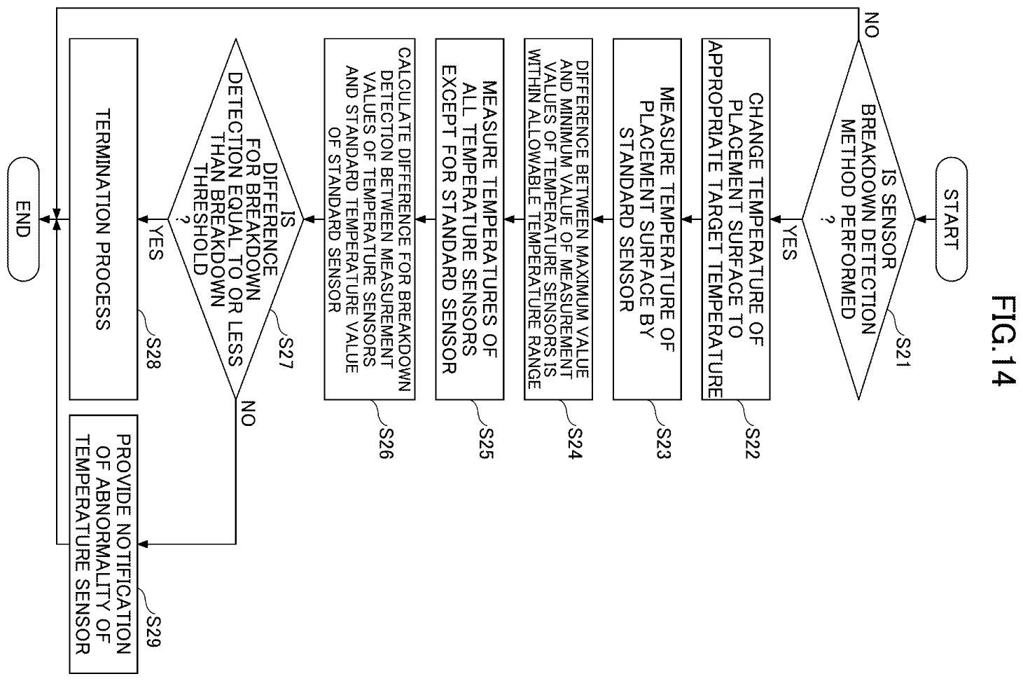

FIG. 14 is a flowchart illustrating a process flow of the sensor breakdown detection method. As illustrated in FIG. 14, upon operation of the inspection apparatus 1, the prober controller 80 first determines whether or not to perform the sensor breakdown detection method (step S21). For example, the prober controller 80 shows a breakdown detection flag during a period from the previous time at which the temperature calibration method or the sensor breakdown detection method is performed, during a cumulative period for which the inspection of the wafer W is performed, or in the case in which there is a predetermined difference or greater in the measurement values of the temperature sensor 77. Then, the prober controller 80 performs the sensor breakdown detection method when the breakdown detection flag is 1 as a result of referring to the breakdown detection flag at a timing, such as upon start-up of the inspection apparatus 1, before start of inspection of the wafer W, during stand-by of inspection of the wafer W, or the like. When the breakdown detection flag is 0, the prober controller 80 determines that the sensor breakdown detection method is not performed (step S21: NO) and proceeds to inspection of the wafer W.

When the sensor breakdown detection method is performed (step S21: YES), the prober controller 80 drives the temperature control mechanism 73 to change the temperature of the placement surface 751 of the chuck 70 to an appropriate target temperature (step S22). No particular limitation is imposed on the target temperature, which is however, for example, a temperature set upon inspection of the wafer W (e.g., 85° C.), or a standard temperature (e.g., −55° C., 25° C., or 155° C.) that is the target temperature in the temperature calibration method. The prober controller 80 may perform the sensor breakdown detection method only at one target temperature, or may perform the sensor breakdown detection method for each of the plurality of target temperatures. When the sensor breakdown detection method is performed at one target temperature, the time it takes for necessary work can be shortened. Conversely, when the sensor breakdown detection method is performed at the plurality of target temperatures, accuracy of breakdown detection can be increased.

In controlling the temperature of the placement surface 751 by the temperature adjustment mechanism 73, the prober controller 80 measures the temperature of the placement surface 751 by the standard sensor 77A, and stores the measurement result in the memory (step S23). Moreover, the prober controller 80 sets a state in which the difference between the maximum value and the minimum value of the measurement values during a predetermined stabilization period is within an allowable temperature range (step S24).

Subsequently, the prober controller 80 measures the temperature of the placement surface 751 at each of the detection positions for all of the temperature sensors 77 except for the standard sensor 77A, and stores the measurement results in the memory (step S25). At this time, the prober controller 80 may measure the temperature by each of the temperature sensors 77 over a predetermined period, and monitor whether or not the difference between the maximum value and the minimum value of the measurement values is within the allowable temperature range (e.g., ±0.5° C.) and extract the measurement value at the end of the predetermined period.

When the temperature of the temperature sensor 77 is measured, the prober controller 80 calculates a difference for breakdown detection between: the measurement values of the temperature sensors 77 except for the standard sensor 77A; and a reference temperature value (measurement value) of the standard sensor 77A (step S26). The difference for breakdown detection is preferably calculated as an absolute value.

Next, the prober controller 80 compares the difference for breakdown detection of each of the temperature sensors 77 except for the standard sensor 77A, with a breakdown threshold recorded in advance, and determines whether or not the difference for breakdown detection is equal to or less than the breakdown threshold (step S27). No particular limitation is imposed on the breakdown threshold as long as the breakdown threshold is an appropriate value that is indicative of breakdown of the sensor. The breakdown threshold may be set to, for example, 1° C. When the difference for breakdown detection is equal to or less than the breakdown threshold, the temperature sensor 77 of interest can be regarded to be free of abnormalities, such as breakdown or the like. When all of the temperature sensors 77 except for the standard sensor 77A are normal (step S27: YES), the prober controller 80 proceeds to step S28 and performs a termination process of the sensor breakdown detection method. In the termination process, the prober controller 80 returns the breakdown detection flag to 0, and identifies the next operation of the inspection apparatus 1 (e.g., start of inspection of the wafer W) and, for example, re-sets the target temperature of the temperature adjustment mechanism 73 and proceeds to another control.

Meanwhile, when the difference for breakdown detection exceeds the breakdown threshold (step S27: NO), the temperature sensor 77 of interest can be regarded to involve abnormalities, such as breakdown or the like. Therefore, when the prober controller 80 determines that even one of the temperature sensors 77 is abnormal, the process flow proceeds to step S29. In step S29, the prober controller 80 notifies a user of information that abnormality is occurring in the temperature sensor 77 of the prober 50, via the user interface of the control unit 9. Thereby, the user can readily identify the abnormality of the temperature sensor 77 at an early stage.

### Third Embodiment

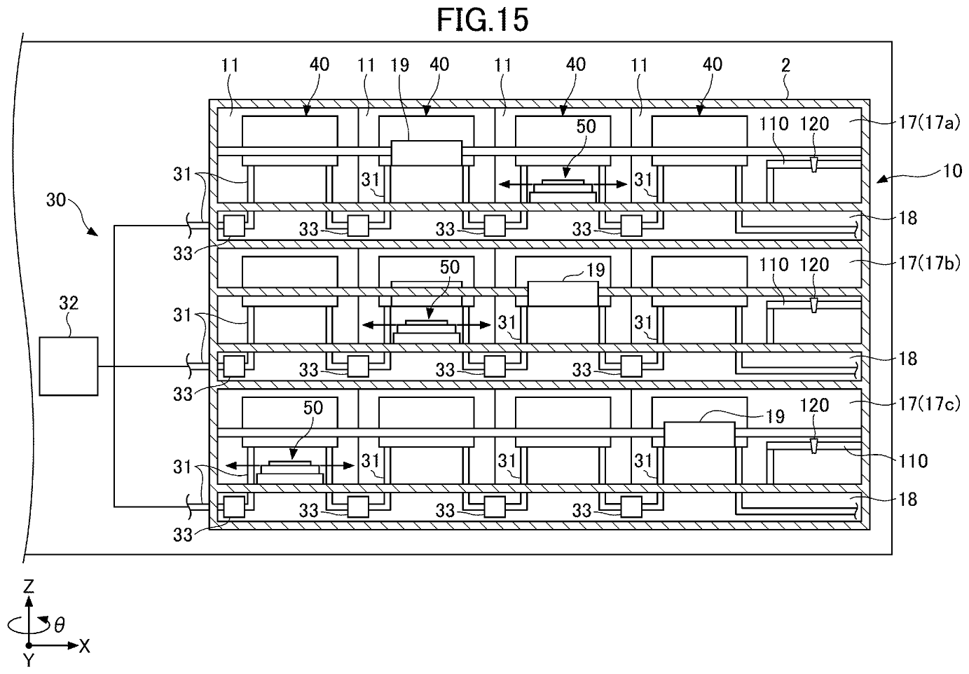

FIG. 15 is a schematic explanatory view illustrating an inspection apparatus 1A including the temperature calibration system 100 according to the third embodiment. As illustrated in FIG. 15, the inspection apparatus 1A may be configured to automatically calibrate each of the temperature sensors 77 of the chuck 70 if necessary (or at predetermined intervals) by including the temperature calibration system 100 in the casing 2. For example, the inspection apparatus 1A includes the surface thermometer 120 of the temperature calibration system 100 laterally of the inspection chamber row 16.

Upon start of the temperature calibration method, the inspection apparatus 1A moves the prober 50 along the X-Y-axis direction so that the placement surface 751 of the chuck 70 faces the surface thermometer 120. After the arrangement of the prober 50, the prober controller 80 performs the temperature calibration method in accordance with the process flow as illustrated in FIG. 11, so that the temperature sensors 77 can be calibrated even in the course of the operation process after the initial installation or maintenance of the inspection apparatus 1. Upon maintenance or the like of the inspection apparatus 1, the surface thermometer 120 preferably ensures traceability by calibrating the surface thermometer 120 with the standard 200 that is in conformity to the national standard.

Technical ideas and effects of the present disclosure described in the above embodiments will be described below.

A first aspect of the present disclosure is the temperature calibration system 100 including: the inspection apparatus 1 configured to adjust the temperature of the inspection target (wafer) placed on the placement part (chuck 70) and inspect the inspection target; and the surface thermometer 120. The temperature calibration system 100 is configured to calibrate the plurality of temperature sensors 77 provided in the placement part. The inspection apparatus 1 includes: the carriage 56 configured to move the placement part in the X-axis direction, the Y-axis direction, and the Z-axis direction; and the controller (prober controller 80) configured to perform the calibration process to measurement values of the plurality of temperature sensors 77. The surface thermometer 120 is configured to contact the placement surface 751 of the placement part and detect the surface temperature of the placement surface 751. The controller is configured to: control the carriage 56 to contact the surface thermometer 120 with the detection position of the placement surface 751 of the placement part; detect the surface temperature of the detection position by the surface thermometer 120; and calibrate the measurement value of the temperature sensor 77 corresponding to the detection position based on the surface temperature of the detection position.

According to the above, the temperature calibration system 100 performs calibration of the plurality of temperature sensors 77 using one surface thermometer 120, and can accurately calibrate the measurement value of each of the temperature sensors 77 while avoiding variation in calibration caused by a device. In addition, because the temperature calibration system 100 moves the placement part (chuck 70) in conjunction with the carriage 56 to contact the surface thermometer 120 with the detection position, an error with respect to the detection position of the temperature sensor 77 can be suppressed, and the surface temperature can be accurately obtained.

The surface thermometer 120 also includes: the contact body 123 that is to contact the placement surface 751; and the detection element 124 that projects outward of the contact body 123 and is elastically deformable upon contact with the placement surface 751. Thereby, the surface thermometer 120 enables the detection element 124 to maintain the same elastically deformed shape in a state in which the placement surface 751 is in contact with the contact body 123, and can increase the detection accuracy of the surface temperature for each of the temperature sensors 77.

The contact body 123 is formed in an annular shape for housing a part of the detection element 124, and the detection element 124 is formed into a plate thinner than the thickness of the contact body 123. The thin-plate plate shaped detection element 124 has a small heat capacity, and a faster heat responsiveness. This can efficiently perform the calibration process of the plurality of temperature sensors 77. Moreover, by contacting the surface of the annular contact body 123 with the placement surface 751, the shape of the detection element 124 can be more surely identical.

The surface thermometer 120 is attached to the jig 110 that is to be fixed to the plurality of supports 54 provided around the placement part. The surface thermometer 120 is disposed above the placement surface 751. Thereby, the temperature calibration system 100 can perform calibration of each of the temperature sensors 77 by applying the carriage 56 of the inspection apparatus 1 configured to move the placement part. This can simplify the system.

The jig 110 also includes the relief structure 115 configured to retain the surface thermometer 120 so as to be displaceable in the Z-axis direction. The relief structure 115 relieves the pressing force received from the placement surface 751 upon contact between the surface thermometer 120 and the placement surface 751. Thereby, the temperature calibration system 100 can obtain a surface temperature with higher reproducibility because the own weight of the surface thermometer 120 or the pressing force applied to the detection element 124 works equally.

The controller (prober controller 80) includes the storage (data logger 130) configured to store the temperature sensor 77 at the detection position in association with the surface temperature of the detection position detected by the surface thermometer 120. Thereby, the temperature calibration system 100 can readily accumulate the surface temperature detected by the surface thermometer 120 and the position of the temperature sensor 77.

In the calibration process, the controller (prober controller 80) performs calibration of the measurement value for each of the target temperatures by the temperature adjustment mechanism 73, and obtains the calibration curve for each of the temperature sensors 77 based on the calibration result for each of the target temperatures. Thereby, the controller can accurately obtain the temperature distribution of the placement surface 751 of the inspection target (wafer W) by the measurement value of each of the temperature sensors 77.

Moreover, at least one of the temperature sensors 77 is provided in the stable area SA in which the temperature is stabilized in the placement surface 751. The controller (prober controller 80) controls the temperature of the placement part (chuck 70) based on the measurement value of the temperature sensor 77 of the stable area SA in the calibration process. Thereby, the temperature calibration system 100 can perform the calibration process of each of the temperature sensors 77 in a state in which the temperature of the placement part is surely stabilized.

The detection value of the surface thermometer 120 is calibrated to a value conforming to the national standard. Thereby, the temperature calibration system 100 can trace to the measurement values of the temperature sensors 77 calibrated by the surface temperature detected by the surface thermometer 120, with respect to the national standard.

Moreover, the temperature sensors 77 include at least one standard sensor 77A. The controller compares the standard value measured by the standard sensor 77A with the measurement values obtained by the temperature sensors 77 except for the standard sensor 77A. When the measurement value deviates from the standard value by a predetermined level or more, the controller determines that an abnormality occurs in the temperature sensor 77 in which the measurement value deviates from the standard value. Thereby, the temperature calibration system 100 can readily and accurately identify normality or abnormality of each of the temperature sensors 77 on a regular basis or if necessary.

Moreover, the standard sensor 77A is provided in the stable area SA in which the temperature is stabilized in the placement surface 751. Thereby, the standard sensor 77A can stably measure the temperature of the placement surface 751.

A second aspect of the present disclosure is the inspection apparatus 1 configured to inspect the inspection target. The inspection apparatus 1 includes: the placement part (chuck 70) configured to place the inspection target (wafer W) and adjust the temperature of the inspection target; the temperature sensors 77 provided in the placement part; the carriage 56 configured to move the placement part in the X-axis direction, the Y-axis direction, and the Z-axis direction; and the controller (prober controller 80) configured to perform the calibration process to the measurement values of the temperature sensors 77. The inspection apparatus 1 further includes the surface thermometer 120 configured to contact the placement surface 751 of the placement part and detect the surface temperature of the placement surface 751. The controller controls the carriage 56 to contact the surface thermometer 120 with the detection position of the placement surface 751 of the placement part; detects the surface temperature of the detection position by the surface thermometer 120; and calibrates the measurement value of the temperature sensor 77 corresponding to the detection position based on the surface temperature.

A third aspect of the present disclosure is a temperature calibration method of calibrating the temperature sensors 77 provided in the placement part in the inspection apparatus 1 configured to adjust the temperature of the inspection target (wafer W) placed on the placement part (chuck 70) and inspect the inspection target; and the surface thermometer 120. The temperature calibration method includes: a first step of adjusting the temperature of the placement part; a second step of moving the placement part by the carriage 56 that is movable in the X-axis direction, the Y-axis direction, and the Z-axis direction and contacting the surface thermometer 120 with the detection position of the placement surface 751 of the placement part; and a third step of detecting the surface temperature of the detection position of the placement surface 751 by the surface thermometer 120 and calibrating the measurement value of the temperature sensor 77 corresponding to the detection position based on the surface temperature. During the first step, the first step and the second step are repeatedly performed for all of the temperature sensors 77.

In both of the second aspect and the third aspect that are described above, the temperature sensors 77 can be calibrated with high accuracy.

The temperature calibration system 100, the inspection apparatus 1, and the temperature calibration method according to the embodiments disclosed herein are exemplary in all respects and are not restrictive. The embodiments can be modified and improved in various forms without departing from the scope of the appended claims and the gist thereof. The matters described in the above two or more embodiments can have other configurations to the extent that no contradiction occurs, or can be combined to the extent that no contradiction occurs. For example, the inspection target to be inspected by the inspection apparatus 1 is not limited to the substrate (wafer W) and may be a variety of electrical and electronic devices that require an electrical inspection. The inspection apparatus 1 is not limited to one including the plurality of inspection units 40 (testers 41) and may be an inspection apparatus including the single inspection unit 40. Even in this case, the prober 50 can adjust the temperature of the chuck 70 by including the temperature adjustment mechanism 73 and the plurality of temperature sensors 77, and can move the chuck 70 on which the wafer W is placed. By the above-described temperature calibration method, the plurality of temperature sensors 77 can be efficiently calibrated.

The temperature calibration system 100 of the present disclosure is not limited to one that performs calibration of the plurality of temperature sensors 77 provided in the chuck 70 of the inspection apparatus 1. For example, the temperature calibration system 100 may perform calibration of the plurality of temperature sensors 77 in a configuration in which the plurality of temperature sensors 77 are provided in the placement part (e.g., the stage, the chuck, or the like) installed in a process chamber of a substrate processing apparatus.

This application is based upon and claims priority to basic application No. 2021-162244, filed on Sep. 30, 2021 with the Japan Patent Office, the entire contents of which are incorporated herein by reference.

### REFERENCE SIGNS LIST

1 inspection apparatus
56 carriage
70 chuck
751 placement surface
77 temperature sensor
80 prober controller
100 temperature calibration system
120 surface thermometer
W wafer

1. A temperature calibration system, comprising:
an inspection apparatus configured to adjust a temperature of an inspection target placed on a placement part and inspect the inspection target; and
a surface thermometer, wherein
the temperature calibration system is configured to calibrate a plurality of temperature sensors provided in the placement part,
the inspection apparatus includes
a carriage configured to move the placement part in an X-axis direction, a Y-axis direction, and a Z-axis direction, and
a controller configured to perform a calibration process to measurement values of the plurality of temperature sensors,
the surface thermometer is configured to contact a placement surface of the placement part and detect a surface temperature of the placement surface, and
the controller includes
a processor, and
a memory storing one or more programs, which when executed, cause the processor to:
control the carriage to contact the surface thermometer with a detection position of the placement surface of the placement part,
detect the surface temperature of the detection position by the surface thermometer, and
calibrate the measurement value of the temperature sensor corresponding to the detection position based on the surface temperature.

2. The temperature calibration system according to claim 1, wherein the surface thermometer includes:
a contact body that is to contact the placement surface; and
a detection element that projects outward of the contact body and is elastically deformable upon contact with the placement surface.

3. The temperature calibration system according to claim 2, wherein
the contact body is formed in an annular shape for housing a part of the detection element, and
the detection element is formed into a plate thinner than a thickness of the contact body.

4. The temperature calibration system according to claim 1, wherein
the surface thermometer is attached to a jig that is to be fixed to a plurality of supports provided around the placement part, and
the surface thermometer is disposed above the placement surface.

5. The temperature calibration system according to claim 4, wherein
the jig includes a relief structure configured to retain the surface thermometer so as to be displaceable in the Z-axis direction, and
the relief structure is configured to relieve a pressing force received from the placement surface upon contact between the surface thermometer and the placement surface.

6. The temperature calibration system according to claim 1, wherein
the controller includes a storage configured to store the temperature sensor of the detection position in association with the surface temperature of the detection position detected by the surface thermometer.

7. The temperature calibration system according to claim 1, wherein
in the calibration process, the one or more programs, which when executed, cause the processor to:
perform calibration of the measurement value for each of a plurality of target temperatures by a temperature adjustment mechanism, and
obtain a calibration curve for each of the temperature sensors based on a calibration result for each of the plurality of target temperatures.

8. The temperature calibration system according to claim 1, wherein
at least one of the plurality of temperature sensors is provided in a stable area in which a temperature is stabilized in the placement surface, and
in the calibration process, the one or more programs, which when executed, cause the processor to:
control a temperature of the placement part based on the measurement value of the temperature sensor in the stable area.

9. The temperature calibration system according to claim 1, wherein
a detection value of the surface thermometer is calibrated to a value that is in conformity to a national standard.

10. The temperature calibration system according to claim 1, wherein
the plurality of temperature sensors include at least one standard sensor,
the one or more programs, which when executed, cause the processor to:
compare a standard value measured by the standard sensor with the measurement values obtained by the temperature sensors except for the standard sensor, and
in a case in which the measurement value deviates from the standard value by a predetermined amount or more, determine that an abnormality occurs in the temperature sensor in which the measurement value deviates from the standard value.

11. The temperature calibration system according to claim 10, wherein
the standard sensor is provided in a stable area in which a temperature is stabilized in the placement surface.

12. An inspection apparatus, which is configured to inspect an inspection target, the inspection apparatus comprising:
a placement part configured to place the inspection target and adjust a temperature of the inspection target;
a plurality of temperature sensors provided in the placement part;
a carriage configured to move the placement part in an X-axis direction, a Y-axis direction, and a Z-axis direction; and
a controller configured to perform a calibration process to measurement values of the plurality of temperature sensors, wherein
the inspection apparatus includes a surface thermometer configured to contact a placement surface of the placement part and detect a surface temperature of the placement surface,
the controller includes
a processor, and
a memory storing one or more programs, which when executed, cause the processor to:
control the carriage to contact the surface thermometer with a detection position of the placement surface of the placement part,
detect the surface temperature of the detection position by the surface thermometer, and
calibrate a measurement value of the temperature sensor corresponding to the detection position based on the surface temperature.

13. A temperature calibration method of calibrating a plurality of temperature sensors provided in a placement part in an inspection apparatus configured to adjust a temperature of an inspection target placed on the placement part and inspect the inspection target, and a surface thermometer, the temperature calibration method comprising:
a) adjusting a temperature of the placement part;
b) moving the placement part by a carriage that is movable in an X-axis direction, a Y-axis direction, and a Z-axis direction and contacting the surface thermometer with a detection position of a placement surface of the placement part; and
c) detecting a surface temperature of the detection position of the placement surface by the surface thermometer and calibrating a measurement value of the temperature sensor corresponding to the detection position based on the surface temperature, wherein
during a), a) and b) are repeatedly performed for all of the temperature sensors.
